(19) United States
(12) Patent Application Publication
(10) Pub. No.: US 2009/0131295 A1
(43) Pub. Date: May 21, 2009

(54) Compositions for Removal of Metal Hard Mask Etching Residues from a Semiconductor Substrate

(76) Inventor: Hua CUI, Castro Valley, CA (US)

Correspondence Address: MORGAN LEWIS & BOCKIUS LLP, 1111 PENNSYLVANIA AVENUE NW, WASHINGTON, DC, 20004, US

(21) Appl. No.: 12/239,999

(22) Filed: Sep. 29, 2008

Related U.S. Application Data
(60) Provisional application No. 60/996,429, filed on Nov. 16, 2007.

(51) Int. Cl. G03F 7/42

(52) U.S. Cl. 510/176

(57) ABSTRACT

Compositions for removing and cleaning resist, etching residues, planarization residues, metal fluorides and/or metal oxides from a substrate are provided, the composition including a metal ion-free fluoride compound and water. The resist, etching residues, planarization residues, metal fluorides and/or metal oxides are generated during one or more patterning processes during which a metal hard mask is used.

The present application claims the benefit of U.S. Provisional Application No. 60/996,429, filed on Nov. 16, 2007, which is incorporated by reference in its entirety.

### FIELD OF THE INVENTION

The present invention relates generally to cleaning and etching compositions and a process for removal of residues and contaminants such as polymers, metal oxides, organics and organometallics, and/or metallics, etc. from a semiconductor substrate. More particularly, the present invention relates to the removal of residues using a composition comprising selected fluoride compounds. The invention also relates to a non-corrosive composition useful for the cleaning and etching of many combinations of metals and dielectric compounds. The compositions of the invention are especially useful for cleaning and removing residues in the dual damascene semiconductor manufacturing processes where hard mask layers such as titanium, aluminum, tantalum or alloys such as titanium nitride (TiN), tantalum nitride (TaN), alumina (Al₂O₃); silicon oxynitride (SiON) and silicon carbonitride (SiCN) are used to assist in patterning of the dual damascene structure for subsequent metal fill, and act as highly selective CMP stop layers.

### DESCRIPTION OF THE RELATED ART

Modern integrated circuits typically comprise millions of active transistors on a single substrate, electrically interconnected through the use of single and multilevel interconnections including conductive lines and plugs (“vias”). As the industry develops processes for the 65 nm and 45 nm technology nodes, post etch/ash cleaning faces new challenges with far more stringent requirements on surface cleanliness and materials loss. The introduction and integration of new materials, such as metal hard mask, creates additional requirements for wafer cleaning due to the occurrence of new defect modes related to metal hard mask. In the dual damascene Cu/low-k process flow with hard mask, there are three typical residues remaining after etch/ash: generic polymer residue, organometallic residue strongly bonded to a metal mask, and time-dependent metal fluoride residue.

### I. Introduction

As complementary metal-oxide-semiconductor (CMOS) transistor scaling proceeds into the deep sub-micron regime, the number of transistors on high performance, high density integrated circuits (ICs) is in the tens of millions, in accordance with the historical trend of Moore's Law. The signal integration of many active elements has necessitated that such ICs feature as many as eight layers of high density metal interconnect. The electrical resist and parasitic capacitance associated with these metal interconnections have become a major factor that limits the circuit speed of such high performance ICs.

Electrical resist and parasitic capacitance are also the fundamental motivating factor causing the semiconductor industry to move away from aluminum interconnect metal with silicon dioxide dielectric between the metal lines, to copper metal and low-k dielectric materials. Copper reduces the resist of the metal interconnect lines and increases their reliability, while low-k dielectrics reduce the parasitic capacitance between the metal lines. These new materials are employed in a fabrication process called “dual damascene” which is used to create the multi-level, high density metal interconnections needed for advanced, high performance ICs. The initial transition to dual damascene processes employed copper metal with traditional silicon dioxide dielectric. More recently, the trend has moved toward the replacement of silicon dioxide dielectric with new low-k dielectric materials. The transition to porous low-k dielectrics, combined with copper metallization, poses a significant integration problem for the dual damascene process.

Although either the trench or the via can be etched first in a dual damascene process, most semiconductor manufacturers have chosen to adopt the via-first approach. However, this methodology, and other aspects of the dual damascene process, particularly barrier materials, may be forced to undergo a revision as the unique and frequently fragile properties of low-k dielectrics are taken into consideration. In order to appreciate the details of this integration challenge, it is useful to review the processing options available for the formation of dual damascene structures.

Because copper does not form a volatile by-product, it is very difficult to etch, and therefore copper metallization schemes cannot be realized using the traditional subtractive etching approach used to form aluminum metal lines. The dual damascene technique overcomes this problem by etching a columnar hole, followed by a trench etch into the inter-layer dielectric (ILD), and then filling both structures with copper which is subsequently polished back (using chemical mechanical polishing (CMP)) to the surface of the ILD. The result is a vertical copper via connection and an inlaid copper metal line. A key issue here are which of the two etches in the dual damascene process, the via etch or the trench etch, should be performed first, and how to select an appropriate barrier material.

### II. The Trench-First Approach

In this methodology, the wafers are coated with photoresist, lithographically patterned, and an anisotropic dry etch cuts through both the surface hard mask (typically plasma silicon nitride), and the low-k dielectric, stopping on the embedded etch stop layer (also typically silicon nitride). The photoresist is then stripped, leaving behind a trench in the ILD. The surface hard mask on top of the ILD is required to protect the ILD from the photoresist stripping process. The reason is that the low-k materials that form the ILD are susceptible to the same chemicals that strip photoresist. In addition, the surface hard mask acts as a CMP stop in the subsequent copper polishing.

Next, photoresist is again applied to the wafers and lithographically patterned. The via etch then cuts through both the embedded etch stop layer and the ILD, to the final silicon nitride barrier located at the bottom of the via. The bottom barrier is then opened with a special etch and the photoresist is stripped.

Next, a tantalum barrier layer is deposited on the dual damascene structure and acts as a barrier to prevent the copper (deposited in the next operation) from diffusing into the ILD. A copper seed layer is then deposited using physical vapor deposition (PVD) and the bulk copper is deposited via electroplating. The copper is further polished using CMP back to the surface of the trenches, followed by deposition of a silicon nitride barrier layer. Therefore, as a result of these steps, the dual damascene structure is completed.

The major drawback of the trench-first approach is that after the trench is etched, the photoresist applied for the via step will completely fill these trenches (see FIG. 1). Thus, the photoresist is said to have “pooled” in the trenches, creating local regions of extra strong resist right in the areas where the vias are to be patterned. Forming the very fine via structures in such strong resist is extremely difficult, and the processing margin for via formation becomes untenable within limited geometries. As a result, the trench-first approach to dual damascene formation has largely been abandoned at the 0.25 μm technology node.

### III. The Via-First Approach

In this methodology, the wafers are first coated with photoresist and then lithographically patterned. Second, an anisotropic etch cuts through the surface hard mask the ILD, and the embedded etch stop before stopping at the bottom silicon Nnitride barrier layer. It is important that the via etch does not break through this bottom layer. If the bottom layer is broken through, the via etch will sputter the copper located beneath the barrier up into the unprotected via hole. The copper will then quickly diffuse into the ILD, causing the failure of the device. Third, the via photoresist layer is stripped, and the trench photoresist is applied and lithographically patterned. Some of the photoresist will remain on the bottom of the via (see FIG. 2), and prevent the lower portion via from being over-etched during the trench etch process.

An anisotropic etch further cuts through both the surface hard mask and the ILD, stopping at the embedded hard mask. This etch forms the trench. The photoresist is then stripped and the silicon nitride barrier at the bottom of the via is opened with a low-energy etch that does not cause any underlying copper to sputter into the via.

Finally, the tantalum, copper seed and bulk copper are deposited and planarized using CMP, as previously described in the trench-first approach.

The via-first approach has been widely adopted for small geometry devices because it avoids the photoresist pooling effect that occurs when the trenches are formed before the vias. The only pooling of photoresist that occurs happens at the bottom of the already formed via, and it has the beneficial effect of shielding the lower via from the trench etch.

### IV. Integration Challenges

Although the via-first approach has been very successful for dual damascene implementation in silicon dioxide, fluorinated silicate glass (FSG), and some early versions of low-k materials, it faces a severe challenge when used with ultra low-k materials. This is due to the fact that in the via-first approach, residual photoresist remains behind in the bottom of the via during the trench etch, as previously mentioned. However, the highly porous nature of ultra low-k dielectrics may cause further contamination and alteration of its k value because of the absorption of this residual photoresist by the ILD.

This drawback may necessitate the return to a modified trench-first approach to the dual damascene fabrication. However, even this approach is at risk, because the trench-first approach photoresist pools in the open trench structure prior to via patterning (FIG. 1). In addition, the use of the trench-first methodology at device nodes below 0.25 μm would require the development of a thin resist imaging process in order to accommodate the patterning of fine via structures through the pooled resist in the trenches.

Further problems concerning ultra low-k dielectrics arise with regard to CMP. Most low-k films are hydrophilic in nature, and it is critical that the surface hard mask, located on the top of the ILD stack, shields the ILD from moisture during the copper CMP process, and protects the ILD from aggressive cleaning. The low-k films must also block the copper diffusion and act as CMP stops.

Furthermore, when the barrier material is used in the middle of the ILD stack, it must behave as an embedded etch stop. This requirement means that the barrier etch rate must be significantly slower than that of the ILD in order to ensure adequate etch selectivity.

Currently, silicon nitride is the material employed to perform those multiple roles. However, as the industry drives toward lower and lower ILD k values, the permittivity of silicon nitride (6<k<8) becomes unacceptable. Its relatively high permittivity undesirably raises the overall permittivity of the ILD stack, compromising the stack's ability to mitigate electrical delay. Other materials with lower k values, such as amorphous silicon carbide (SiCH), have been investigated and found to be promising substitutes for silicon nitride. SiCH with good adhesive properties, is chemical inert, and therefore makes an excellent CMP stop. It can also form a good etch stop layer due to its slower etch rate relative to other low-k materials. The etch stop layer will further be a good barrier to block moisture and copper diffusion.

Since the barrier material is a central component of the low-k/dual damascene structure, any changes of such a fundamental component cannot be done without a comprehensive study of its nature, and will be carried out only if this change is absolutely necessary. This issue is further challenged by the undetermined character of the ILD material to be used for future devices. With many different candidates competing for the role of low-k dielectric ILD, such as spin-on versus CVD, fluorinated versus non-fluorinated organic polymers, etc., the issue needs to be settled before an entirely new barrier material can be implemented. In particular, the proliferation of low-k materials is a major obstacle to resolving the dual damascene/low-k integration problem.

### V. Hard Masks

Hard masks for dual damascene interconnect processing have primarily been dielectric films, such as SiN, SiC and SiON. They have two main functions: to assist in patterning of the dual damascene structure for subsequent metal fill, and as a highly selective CMP stop layer. In addition, the masks can be used to prevent fast diffusion of acid or base moieties that could interact detrimentally with the traditional acid-catalyzed photoresist systems employed at 248 nm and 193 nm.

More recently, with the introduction of porous low-k films, the industry trend is to use metal hard masks, typically titanium- or tantalum-based versions. A metal hard mask provides the best protection against resist poisoning, and works well for the porous low-k. In practice, a layer of photoresist and an underlying an antireflective coating (ARC) layer are underlain by a layer of metal. The first step is a hard mask open to etch the trench width through this metal layer. Second, the wafer is ashed, exposing the remaining metal. Third, another ARC is deposited and patterned for the via etch. This procedure protects the partial trench while the via width is etched to partially open the barrier layer, followed by another ashing step. An ARC is deposited once again and patterned for completing the trench etch. After the trench is etched, any ARC remaining on the bottom of the via is removed in the ashing step before the barrier layer (partially opened during the initial via etch) is completely opened to the copper-filled trench below.

The main challenge of etching a metal hard mask is that the byproducts have a low volatility and the resulting post etch residues are far more difficult to remove than with non-metal hard masks. FIG. 3A and FIG. 3B illustrate the residues remaining on the substrate surface after patterning processes.

During etch and/or ash processing, the low k dielectric materials are damaged by depleting the carbon contents in the low k dielectrics. Accordingly, a wet removal process is preferred.

Where Al₂O₃ is employed as a metal hard mask for Cu-low-k dual damascene scheme, there are some advantages related to etch selectivity. Under the proper chemical conditions, removal of the hard mask can be carried out in the same step as post etch cleaning to minimize processing costs. Using this scheme, the line-to-line capacitance reduces by 10% because no ashing is applied after low-k trench etching. Low-temperature deposition of Al₂O₃ is found to be the key for the dissoluble property. When the deposition temperature is 100° C. or less, a wide range of conventional post etch cleaning solutions can be used to remove the remaining Al₂O₃ hard mask.

Another example disclosed in U.S. Pat. No. 6,696,222, which is incorporated herein by reference in its entirety, describes a method of forming a dual damascene structure using metallic material, such as Ti, TiN, Ta, TaN, Al or AlCu as the hard mask layer.

FIG. 4 shows a structure with two metal hard mask layers. In FIG. 4, a semiconductor substrate (30) comprises a plurality of metal wire structures (32), a dielectric separation layer (34) covering the metal wire structures (32) and the exposed substrate (30), and a low-k dielectric layer (36) formed on the dielectric separation layer (34). The dielectric separation layer (34) prevents the metal wire structures (32) from oxidizing and prevents the ions in the metal wire structures (32) from diffusing into the low-k dielectric layer (36). Preferably, the metal wire structure (32) is copper, and the dielectric separation layer (34) is silicon nitride or silicon carbide. The low-k dielectric layer (36) is made of organic materials, such as spin-on polymer (SOP), FLARE, SILK, PARYLENE and/or PAE-11, and formed through a spin-coating process. Alternatively, the low-k dielectric layer (36) is made of Si-based materials, such as SiO, fluorinated silicon glass (FSG), or USC, and formed through a spin-coating process, or BLACK DIAMON, CORAL, AURORA, and FLOWFILL, and formed through a chemical vapor deposition (CVD) Process. In addition, a first hard mask (38) and a second hard mask (40) are sequentially formed on the low-k dielectric layer (36). Preferably, the first hard mask (38) is made of metallic material, such as Ti, TiN, Ta, TaN, Al, or AlCu. The second hard mask (40) is preferably made of metallic materials, such as Ti, TiN, Ta, TaN, Al or AlCu and alternatively made of dielectric materials, such as SiO, SiC, SiN, SRO or SiON.

As integrated circuit manufacturing has become more complex and the dimensions of circuit elements fabricated on silicon or other semiconductor wafers have become smaller, continued improvement in techniques used to remove residues formed from such materials has been required. Resists, used to mask substrates such that patterned material can be added, need to be removed from substrates.

Many formulations have been developed to remove both positive and negative resist. A resist includes polymeric material, which may be cross-linked or hardened by baking. Therefore, a simple combination of solvents will often remove resists, though time and temperature constraints in the manufacturing process have in general moved the industry to slightly more aggressive compounds.

Etching residue not removed from the substrate can interfere with subsequent processes involving the substrate. The need to effectively remove etching residue and photoresist from a substrate becomes more critical as the industry progresses into submicron processing techniques. Where a metal hard mask is used, the residues become far more difficult to remove and require special formulations that can remove all types of residues generated as a result of plasma etching of various types of metals, such as aluminum, aluminum/silicon/copper, titanium, titanium nitride, titanium/tungsten, tungsten, silicon oxide, polysilicon crystal, etc., while not corroding the underlying metal presents a need for more effective chemical conditions in the processing area. The effect of poor cleaning results in low device yield, low device reliability, and low device performance.

Fluoride containing chemistries have been used for many years to clean prime silicon wafers (wafers that have not yet undergone ion implantation or device construction) in the semiconductor industry. Normally the fluoride chemistry (typically, dilute hydrofluoric acid) is used as the last process step in the sequence called “RCA rinses”. The substrate is often contaminated from previous process steps with monolayer amounts of metal, anions and/or organic contaminants or surface residues (particles). These contaminants have been shown to have a significant impact on the electrical integrity of simple test device structures and they need to be efficiently cleaned without impairing their integrity. Such cleaning methods may include techniques discussed in the technical literature, for example, Int. Conf. On Solid State Devices and Materials, 1991, pp. 484-486 or Kujime, T. et al., Proc. of the 1996 Semi. Pure Water and Chemicals, pp. 245-256 and Singer, P. Semi. International, p. 88, October 1995.

Japanese Patent Appl. No. 2003-122028, to Kenji et al., describes a composition comprising a fluorine compound at a concentration of 0.5% to 10%, greater than 30% of a mixed amide/ether solvent and water, and teaches that at solvent concentrations less than 30% corrosion of the wiring material becomes intense. However, such formulations are not effective at removing etching residues where a metal hard mask is involved.

Japanese Patent Appl. No. 2001-5200, to Yoko et al., describes a resist removing composition for substrates comprising aluminum wiring, the composition comprising 0.1% to 2% ammonium fluoride, 20% to 98.8% of a polar organic solvent, 0.05% to 1.9% ascorbic acid, and 1% to 79.8% water, with pH less than 5.0. The listed polar organic solvents are N,N-dimethylformamide, N,N-dimethylacetamide, dimethyl sulfoxide, ethylene glycol, and propylene glycol. However, such formulations are not effective at removing etching residues where a metal hard mask is involved.

U.S. Pat. No. 5,792,274, to Tanabe et al., describes a remover solution composition for resist which comprises (a) 0.2% to 8% a salt of hydrofluoric acid with a metal-free base, (b) 30% to 90% of a water-soluble organic solvent such as a glycol ether, and (c) water and optionally (d) an anticorrosive, at a pH of 5 to 8. However, such formulations are not effective at removing etching residues where a metal hard mask is involved.

U.S. Pat. No. 5,939,336 describes residue remover compositions of ammonium fluoride, propylene glycol, ammonia and water, at a pH of from 7 to 8. Such formulations are also ineffective at removing etching residues where a metal hard mask is involved.

U.S. Pat. No. 5,972,862 describes a post-etch residue remover having: (A) 0.1% to 15% of a fluoride-containing compound such as hydrofluoric acid or ammonium fluoride; (B) 1% to 80% of a polar organic solvent selected from a list including amides, lactones, alcohols, alkyl acetates, alkyl lactates, alkylene glycols, glycol ethers, and sulfoxides; (C) 0.01% to 5% of an phosphoric acid, phosphorous acid, hypophosphorous acid, polyphosphoric acid, or an organic acid; and (D) 1% to 50% of a quaternary ammonium salt. Water is not a specified component of the remover, and while there is no range specified for water, one example was described as containing 45.9% water. Examples have 1-10% NH₄F, 0.1-1% organic acid, and 35-69% amide solvent, and presumably a balance (˜30% to ˜60%) of water. Similarly, such formulations have been found not to be effective where a metal hard mask is involved.

U.S. Pat. No. 6,235,693 describes residues removers comprising 0.01% to 10% of fluoride compounds, 20% to 50% water, 20% to 80% of a piperidone and from 0 to 50% of an organic sulfoxide or glycol solvent, said composition having a pH between about 6 and about 10. However, such formulations are not effective in removing metal hard mask residues.

U.S. Pat. No. 6,383,410 teaches formulations having the general composition of a chelating agent, preferably weakly to moderately acidic; a fluoride salt, which may be ammonium fluoride or an organic derivative of either ammonium fluoride or a polyammonium fluoride (1.65-7%; preferably 2.25-7%); a glycol solvent (71-98%; preferably 90-98%); and optionally, an amine.

As a result of a continuous effort to decrease critical dimension size in the integrated circuit industry, such as in the fabrication of sub-micron size devices, etching residue removal and substrate compatibility with chemicals employed in wet processing is becoming more and more critical for obtaining acceptable yields in very large scale integration (VLSI) and ultra large scale integration (ULSI) processes. The effectiveness of residue removal by etching, to a large extent, depends on the composition of the surfaces or materials to be etched and the composition of the etchant, as well as many other variables. The composition of such etching residue is generally made up primarily of the etched substrates, underlying substrate, etched and/or ashed photoresist, and etching gases. The substrate compatibility of the wafers with wet chemicals is highly dependent on the processing of the polysilicon, multilevel interconnection dielectric layers, and metallization in thin film deposition, etching and post-etch treatment of the wafers. Processing conditions are often quite different from one fabrication process to another, making it difficult to apply a particular composition to obtain both effective residue removal and substrate compatibility. For example, some compositions have produced corrosion on certain metal substrates, such as those including a titanium metal layer. Titanium has become more widely used in semiconductor manufacturing processes. It is employed both as a barrier layer to prevent electro-migration of certain atoms and as an anti-reflector or refractory metal layer on top of other metals. Used in such a capacity, the layer is often very thin, and corrosion or etching during cleaning operations may compromise the purpose of the layer.

However, further development of integrated circuits and their fabrication processes have created a need for improvement in residue removal compositions and processes.

In a dual damascene opening process using a metal hard mask layer, incomplete removal of sidewall polymer is frequently found in the damascene openings in the central area of the wafer. Thus, the quality of the metal interconnection structure filled in the damascene openings is greatly degraded to decrease the yield of product significantly. This is due to residues from the metal hard mask.

Accordingly, it is an object of this invention to provide such a composition and process which is suitable for removing metal hard mask residues from wafers and other substrates such as titanium, titanium nitrides, silicon nitride which are compatible with copper, as well as other traditional metals, and which are compatible with low-k materials used in semiconductor manufacture.

It is another objective of the invention to provide resist removing compositions that effectively clean resists from metal substrates, inhibit redeposition of metal residues, particularly from the metal hard mask. These and other related objectives are attained through the use of the composition and process disclosed herein.

### SUMMARY OF THE INVENTION

The present invention relates to compositions for cleaning and removing metal hard mask etching residues from semiconductor surfaces without damaging the underlying substrate.

The invention is based in part on the finding that the combination of metal ion-free fluoride compounds with water and, optionally, with one or more acids and/or one or more polar organic solvents selected from the group consisting of amides, alcohol amines, polyols and mixtures thereof synergistically acts to enhance the cleaning ability of the composition to dissolve and remove the metal hard mask etching residue that includes polymers, titanium fluoride and copper oxide. Moreover, the cleaning ability is enhanced unexpectedly at a pH in the range of about 1-8.

The invention is also based in part on the finding that the combination of components discussed in the above paragraph synergistically acts to enhance the cleaning ability of the composition to dissolve and remove the metal hard mask etching residue such as polymers and titanium fluoride and copper oxide. Moreover, the cleaning ability is enhanced unexpectedly at a pH from about 1-8, and more particularly at a pH less than about 5.

In a first embodiment, the invention is directed to a composition for removing one or more of resist, etching residue, planarization residue, metal fluoride and metal oxide, said composition comprising: a) a metal ion-free fluoride compound; and b) water. The pH of this composition is from about 1 to 8, and the composition is capable of removing organic, organometallic, polymer and metal oxide etching residues from the substrates. One or more of resist, etching residue, planarization residue, metal fluoride and metal oxide is generated during one or more patterning processes during which a metal hard mask is used.

In another embodiment, the composition of the invention further comprises one or more acids.

In another embodiment, the composition further comprises one or more polar organic solvents selected from the group consisting of amides, alcohol amines, polyols and mixtures thereof. In another embodiment, one or more polar organic solvents comprises N,N dimethylacetamide.

In another embodiment, the metal ion-free fluoride compound is selected from the group consisting of ammonium fluoride, ammonium bifluoride, HF and mixtures thereof. In another embodiment, the metal ion-free fluoride compound is ammonium bifluoride. The ammonium bifluoride can be present from about 0.005 to about 3 percent by weight, and is preferably present from about 0.01 to about 1.0 percent by weight.

In certain embodiments, the one or more acids can comprise a carboxylic acid, which can be selected from a group consisting of iminodiacetic acid, acetic acid, maleic acid, glyoxylic acid, citric acid, oxalic acid, gallic acid, formic acid, glycolic acid and mixtures thereof. In certain embodiments, the carboxylic acid is in the range of from about 0.5% to about 35% by weight.

In another embodiment, the invention is directed to a composition for removing one or more of resist, etching residue, planarization residue, metal fluoride and metal oxide, wherein said composition comprises: a) a metal ion-free fluoride compound; b) one or more acids; c) a compound selected from the group consisting of ethers, glycol ethers, amides, alcohol amines, polyols and mixtures thereof; and d) water, wherein the pH of the composition is from about 1 to about 8, wherein said composition is capable of removing organic, organometallic, polymer and metal oxide etching residues, and wherein said one or more of resist, etching residue, planarization residue, metal fluoride and metal oxide is generated during one or more patterning processes during which a metal hard mask is used.

In another embodiment, component c) of the immediately above composition comprises propylene glycol and/or one or more of propylene glycol monoethyl ether, diethylene glycol monomethyl ether, diethylene glycol monobutyl ether, or mixture thereof, and wherein component c) is present in the range from about 2% to about 7% by weight. In another embodiment, component c) comprises N,N dimethylacetamide present in the range up to about 60% by weight.

In another embodiment, the above composition comprises a carboxylic acid selected from the group consisting of iminodiacetic acid, acetic acid, maleic acid glyoxylic acid, citric acid, oxalic acid, gallic acid, formic acid, glycolic acid and mixtures thereof. In another embodiment, the carboxylic acid is present in the range from 0.5% to 35% percent by weight.

In other embodiments, the above compositions further comprise a chelating agent. In yet other embodiments, the compositions further comprise monoethanolamine present in the range from about 0.05 to 1% by weight.

In another embodiment, the invention is directed to a method for removing one or more of resist, etching residue, planarization residue, metal fluoride and metal oxide from semiconductor substrate, said method comprising contacting said substrate with the disclosed composition for a period of time and at a temperature sufficient to remove one or more of said resist, etching residue, planarization residue, metal fluoride and metal oxide, wherein one or more of said resist, etching residue, planarization residue, metal fluoride and metal oxide is generated during one or more patterning processes during which a metal hard mask is used, and wherein the compositions have a pH between 1 and 8.

In certain embodiments, the metal hard mask comprises titanium nitride, tantalum nitride, tungsten, chromium, aluminum oxide, aluminum nitride, or mixtures thereof.

In another embodiment, the hard mask etching residue comprises titanium fluoride (TiₓF_{y}), silicon fluoride inorganic residues, copper oxide (CuₓO), polymers, or mixtures thereof.

In another embodiment, the invention is directed to a composition for removing one or more of resist, etching residue, planarization residue, metal fluoride and metal oxide, wherein the composition comprises: ammonium bifluoride, citric acid, propylene glycol and water, wherein the pH of the composition is from about 1 to about 8, and wherein said composition is capable of removing organic, organometallic, polymer and metal oxide etching residues, and wherein said one or more of resist, etching residue, planarization residue, metal fluoride and metal oxide is generated during one or more patterning processes during which a metal hard mask is used.

Yet another embodiment relates to a composition for removing one or more of resist, etching residue, planarization residue, metal fluoride and metal oxide, the composition comprising a) a metal ion-free fluoride compound; b) an acid; c) one or more polar organic solvents selected from the group consisting of amides, alcohol amines, polyols and mixtures thereof; and d) water. The pH of the composition is from about 1 to 8; the composition is capable of removing organic, organometallic, polymer and metal oxide etching residues from substrates; and the one or more of resist, etching residue, planarization residue, metal fluoride and metal oxide is generated during one or more patterning processes during which a metal hard mask is used.

### BRIEF DESCRIPTION OF THE DRAWINGS

In order to facilitate a fuller understanding of the present disclosure, reference is now made to the accompanying drawings. These drawings should not be construed as limiting the present disclosure, but are only intended to be exemplary.

FIG. 1 is an illustrative metal hard-mask dual damascene opening process flow according to the trench-first approach.

FIG. 2 is an illustrative metal hard-mask dual damascene opening process flow according to the via-first approach.

FIG. 3A and FIG. 3B are an illustrative scanning electron microscope (SEM) photographs showing the residues remaining on the semiconductor substrate surface after patterning process.

FIG. 4 is an illustrative structure with two metal hard mask layers.

FIG. 5 is an illustrative dual damascene process using dual hard masks as disclosed in U.S. Pat. No. 6,696,222.

FIG. 6 is an illustrative cross-section of metal hard-mask dual damascene opening process flow according to a preferred embodiment of this invention.

FIG. 7A demonstrates an examination under a Scanning Electron Microscope (SEM), Hitachi SEM 6400, which shows the central feature of a metal hard mask substrate before etching process. FIG. 7B demonstrates an examination under a Scanning Electron Microscope (SEM), Hitachi SEM 6400, which shows the edge feature of a metal hard mask substrate before etching process.

FIG. 8 is a series of illustrative scanning electron microscope (SEM) photographs showing the semiconductor substrate having a metal hard mask via opening after the application of the cleaning composition comprising glycol ether of the present invention, as described in the examples herein.

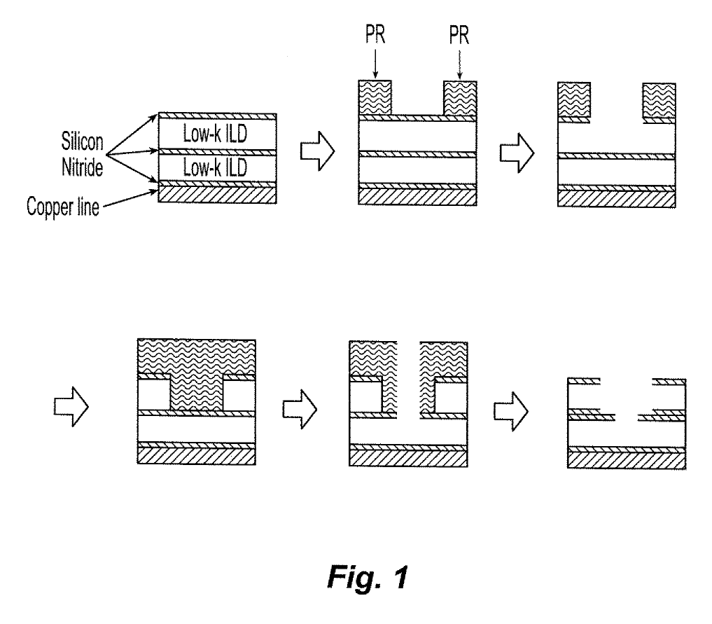

### DETAILED DESCRIPTION OF THE INVENTIONS

### I. Definitions

Unless otherwise specified, all percentages expressed herein should be understood to refer to percentages by weight. Also, the term “about,” when used in reference to a range of values, should be understood to refer to either value in the range, or to both values in the range.

As used herein, the phrases “contains substantially no” and “is substantially free from” in reference to a composition means a negligible amount. For example, substantially free can includes the composition comprising less than 1%, less than 0.5%, less than about 0.1%, or even free of solvents other than polyols or glycol ethers.

As used herein, the term “contacting” refers to any means of bringing the silicon substrate and the compositions of the present invention together physically and includes, but is not limited to, immersing, spraying, micro-droplet fogging, and the like.

The following abbreviations are defined herein.

### MEA: Mono Ethanolamine

TMAH: Tetra-methyl ammonium hydroxide

### PGME: Propylene Glycol Monomethyl Ether

### DDBSA: Dodecyl Benzenesulfonic Acid

### ABF: Ammonium Bifluoride

### PG: Propylene Glycol

### IDA: Iminodiacetic Acid

### DMAC: N,N-Dimethylacetamide

### DIW: De-Ionized Water

### II. Specific Embodiments

### A. Fluoride Providing Component

The fluoride providing component, or, preferably, a metal ion-free fluoride compound, must provide fluoride ions, and may be selected from the group consisting of fluoride-containing acids and/or metal-free salts thereof. The phrase “metal-free salt of fluoride-containing acid” as used herein indicates that metals are not contained in the salt anion or cation. The salt may be formed by combining a fluoride-containing acid such as, but not limited to, hydrogen fluoride, tetrafluoroboric acid, and/or trifluoroacetic acid, with any of ammonium hydroxide; a C₁-C₄ alkyl quaternary ammonium ion such as, but not limited to, tetramethylammonium, tetraethylammonium and trimethyl(2-hydroxyethyl)ammonium; or a primary, secondary or tertiary amine such as, but not limited to, monoethanolamine, 2-(2-aminoethylamino)ethanol, diethanolamine, 2-ethylaminoethanol and dimethylaminoethanol.

Exemplary metal ion-free fluoride compounds include, but are not limited to, hydrogen fluoride and/or its salts; ammonium fluoride and/or ammonium bifluoride (ammonium hydrogen difluoride); fluoroboric or tetrafluoroboric acid and/or its salts, such as ammonium tetrafluoroborate; fluoroacetic or trifluoroacetic acid and/or its salts, such as ammonium trifluoroacetate; fluorosilicic acid and/or its salts, and any mixtures thereof. As used herein, fluorine and fluoride are used interchangeably. Exemplary fluorine-containing compounds include, but are not limited to, hydrogen fluoride, ammonium fluoride, ammonium bifluoride, alkylammonium fluoride, alkylammonium bifluoride, and mixtures thereof, where the alkylammonium fluoride and/or bifluoride comprises 1 to 8 carbon atoms, preferably from 1-4 carbon atoms, and is a mono-, di-, tri-, or tetra-alkylammonium group. In an exemplary embodiment, the fluoride-containing compound consists essentially of ammonium fluoride, ammonium bifluoride, or both. In a further exemplary embodiment, the fluoride-containing compound is ammonium fluoride.

Ammonium salts of hydrogen fluoride represent an exemplary embodiment of the invention. In one embodiment, the dilute solution according to the invention may be substantially free of tetrafluoroboric acid and/or its salts, of trifluoroacetic acid and/or its salts, or both.

The fluorine-containing component may be present at from about 0.005 wt % to about 5.0 wt % as fluorine, such as from about 0.01 wt % to about 0.6 wt % as fluorine, or such as between about 0.015 wt % to about 0.3 wt % as fluorine.

### B. Glycol Ethers

In some embodiments, additional water-miscible organic solvents may be present. The water miscible solvent advantageously comprises, or alternatively consists essentially of, one or more alkyl glycol ethers, hereafter “glycol ethers.” Glycol ethers are well known and include, but are not limited to, mono- or di-alkyl ethers of polyols such as alkyl ethers of ethylene glycol. Exemplary glycol ether species useful in the compositions include but are not limited to ethylene glycol monomethyl ether (EGME), ethylene glycol monoethyl ether (EGEE), ethylene glycol monopropyl ether (EGPE), ethylene glycol monobutyl ether (EGBE), propylene glycol monomethyl ether (PGME), propylene glycol monoethyl ether (PGEE), propylene glycol monopropyl ether (PGPE), propylene glycol monobutyl ether (PGBE), diethylene glycol monomethyl ether (DGME), diethylene glycol monoethyl ether (DGEE), diethylene glycol monopropyl ether (DGPE), diethylene glycol monobutyl ether (DGBE), dipropylene glycol monomethyl ether (DPGME), dipropylene glycol monoethyl ether (DPGEE), dipropylene glycol monopropyl ether (DPGPE), dipropylene glycol monobutyl ether (DPGBE), triethylene glycol monomethyl ether, triethylene glycol monoethyl ether, triethylene glycol monopropyl ether, triethylene glycol monobutyl ether, tripropylene glycol monomethyl ether, tripropylene glycol monoethyl ether, tripropylene glycol monopropyl ether, tripropylene glycol monobutyl ether, and mixtures thereof.

In one embodiment the glycol ether is propylene glycol monoethyl ether, diethylene glycol monomethyl ether, diethylene glycol monobutyl ether, or mixtures thereof. In an exemplary embodiment, the glycol ether is present in the range from about 2% to about 7% by weight.

Optionally in another embodiment, the composition comprises at least about 1 wt % preferably about 3 wt. %, for example, between about 1 to 5 wt % propylene glycol.

### C. Polar Organic Solvents

Polar organic solvents known in the art, other than those specifically excluded herein, can also be used in the compositions of the present invention. As used herein, the term “polar organic solvent” is not intended to encompass ammonium hydroxide or alkyl-substituted ammonium hydroxides. In one embodiment of the invention, the polar organic solvents that are used are miscible with water. In another embodiment of the invention, the term “polar organic solvent” does not encompass low molecular weight amines or alkanolamines.

In an alternate embodiment, the composition according to the invention is substantially free from polar organic solvents as defined herein.

In one embodiment, the compositions according to the invention optionally contain a polar organic solvent. Examples of polar organic solvents for the composition according to the invention include, but are not limited to, sulfoxides such as dimethylsulfoxide, diethylsulfoxide, or methylsulfoxide; sulfones such as dimethyl sulfone, diethyl sulfone, bis(2-hydroxyethyl) sulfone, or tetramethylene sulfone; amides such as N,N-dimethylformamide (DMAC), N-methylformamide, N,N-dimethylacetamide, N-methylacetamide, or N,N-diethylacetamide; lactams such as N-methyl-2-pyrrolidone, N-ethyl-2-pyrrolidone, N-propyl-2-pyrrolidone, N-hydroxymethyl-2-pyrrolidone, N-hydroxyethyl-2-pyrrolidone, or N-methylpyrrolidinone; imidazolidinones such as 1,3-dimethyl-2-imidazolidinone, 1,3-diethyl-2-imidazolidinone, or 1,3-diisopropyl-2-imidazolidinone; lactones such as gamma-butyrolactone or delta-valerolactone; and glycols such as ethylene glycol or diethylene glycol.

In another embodiment the composition comprises from about 20% to about 70% by weight of a polar organic solvent, such as, for example, N,N-dimethylformamide (DMAC).

Sulfoxides and/or amides are generally selected if a second co-solvent is desired. The preferred type of co-solvent, amide versus sulfoxide, can be determined by the types of resists to be encountered, as is taught in published U.S. Application No. 2004/0106531, which is incorporated by reference in its entirety. In an exemplary embodiment, the weight percent of polyols or glycol ethers in the compositions are greater than the weight percent of solvents other than polyols or glycol ethers.

In an alternate embodiment, the compositions according to the invention optionally may include, but are not limited to, benzenesulfonic acid; benzylsulfonic acid (i.e., β-toluenesulfonic acid); alkylbenzenesulfonic acids such as toluenesulfonic acid, hexylbenzenesulfonic acid, heptylbenzenesulfonic acid, octylbenzenesulfonic acid, nonylbenzenesulfonic acid, decylbenzenesulfonic acid, undecylbenzenesulfonic acid, dodecylbenzenesulfonic acid (DDBSA), tridecylbenzenesulfonic acid, tetradecylbenzene sulfonic acid, hexadecylbenzene. In one embodiment, the DDBSA comprises from about 0.02 to 2% by weight of the cleaning composition.

In one embodiment, the composition of this invention comprises from about 0.11% to 4% by weight of tetra-methyl ammonium hydroxide (TMAH).

In other exemplary embodiments of this invention, the compositions are substantially free of solvents other than polyols or glycol ethers. In another embodiment, the compositions are substantially free of sulfones, imidazolidinones, and lactones. In another embodiment, the compositions are substantially free of polyols. In yet another embodiment of the invention, the compositions are substantially free of sulfones, imidazolidinones, lactones, and polyols.

### D. Benzenesulfonic Acids

In one embodiment of the invention, the compositions include, but are not limited to, benzenesulfonic acid; benzylsulfonic acid (i.e., α-toluenesulfonic acid); alkylbenzenesulfonic acids such as toluenesulfonic acid, hexylbenzenesulfonic acid, heptylbenzenesulfonic acid, octylbenzenesulfonic acid, nonylbenzenesulfonic acid, decylbenzenesulfonic acid, undecylbenzenesulfonic acid, dodecylbenzenesulfonic acid (DDBSA), tridecylbenzenesulfonic acid, tetradecylbenzene sulfonic acid, hexadecylbenzene.

In one embodiment, the dodecylbenzenesulfonic acid is in the range from about 0.3% to 4% by weight.

### E. Alkanolamines

In another embodiment, the compositions of the invention further comprise alkanolamines. The alkanolamines suitable for use in the present invention are miscible with polar organic solvents. In an exemplary embodiment, the alkanolamines are water-soluble. In another embodiment, the alkanolamines have relatively high boiling points, such as 100° C. or above, and a high flash point, such as 45° C. or above. In one embodiment, the alkanolamines are primary, secondary or tertiary amines. In an exemplary embodiment, the alkanolamines are monoamines, diamines or triamines. In a particular embodiment, the alkanolamines are monoamines. The alkanol group of the amines preferably has from 1 to 5 carbon atoms.

Examples of suitable alkanolamines include, but are not limited to, mono-ethanolamine (MEA), diethanolamine, triethanolamine, tertiary-butyldiethanolamine isopropanolamine, 2-amino-1-propanol, 3-amino-1-propanol, isobutanolamine, 2-amino-2-ethoxyethanol, and 2-amino-2-ethoxy-propanol.

### F. Acids

In one embodiment, the compositions of the invention comprise, or alternatively consist essentially of, acids, including, but not limited to, organic acids or mixtures of mineral acids and organic acids. The term “acid” as used herein specifically refers to acids other than those acids which provide fluoride. Suitable mineral acids include, but are not limited to, boric acid, phosphoric acid, phosphorous acid, or phosphonic acid. In an exemplary embodiment, the acid is phosphonic acid and/or phosphorus acid.

Preferred organic acids include, but are not limited to mono-, di- and/or tri-carboxylic acids, optionally substituted in a beta position with an hydroxy, carbonyl or amino group. In one embodiment, organic acids suitable for inclusion in the compositions of the invention include, but are not limited to, formic acid, acetic acid, propanoic acid, butyric acid and the like; hydroxy substituted carboxylic acids including, but not limited to, glycolic acid, lactic acid, tartaric acid and the like; oxalic acid; carbonyl substituted carboxylic acids, including but not limited to, glyoxylic acid, and the like; amino substituted carboxylic acids, including but not limited to, glycine, hydroxyethylglycine, cysteine, alanine and the like; cyclic carboxylic acids including, but not limited to, ascorbic acid and the like; oxalic acid, nitrilotriacetic acid, citric acid, and mixtures thereof.

Mono- and di-carboxylic acids having between 1 and 8 carbon atoms, preferably between 2 and 6 carbon atoms, and which may be substituted in an alpha, beta, or alpha and beta positions with an hydroxy and/or carbonyl group, are preferred organic acids. An exemplary embodiment includes organic acids with a carbonyl group substituted on the carbon adjacent to the carboxyl group carbon. Exemplary organic acids include, but are not limited to, iminodiacetic acid, acetic acid, maleic acid glyoxylic acid, citric acid, oxalic acid, sulfamic acid, gallic acid, formic acid, glycolic acid and mixtures thereof. In a particular embodiment, the organic acid is citric acid (C₆H₈O₇) and glyoxylic acid (C₂H₂O₃).

In one embodiment which comprises DMAC (N,N-dimethylacetamide) but without propylene glycol monoethylether (PGME), the organic acid is present in an amount up to about 33%, such as from about 0.3% to about 33% by weight acid. Generally, however, organic acids may have a wide range of carboxylate groups per gram of acid. In one embodiment, the range is between about 0.4% to about 5% by weight acid. Specific examples described herein show positive results with maleic acid (C₄H₆O₅) or citric acid, present at from about 2% to about 35% by weight.

In another embodiment which comprises propylene glycol monoethylether (PGME), the organic acid is advantageously present at up to about 6%, such as from about 2.0% to about 5% by weight acid. Specific examples described herein show positive results with glyoxylic acid (C₄H₆O₅) or citric acid, present at from about 1.5% to about 5% by weight.

In another embodiment which comprises propylene glycol monoethylether (PGME), the organic acid is iminodiacetic acid (IDA), present at from about 0.01% to about 0.070% by weight.

### G. pH

The compositions of the invention clean effectively over a wide pH range, without damaging the semiconductor copper substrate. In one embodiment the pH ranges from between about 1 to about 8. In another embodiment, for compositions with PGME, the pH range is from about 1 to about 7, including, for example, about 3.

Select combinations of components require the addition of acids and/or bases to adjust the pH to an acceptable value. Acids suitable for use in the present invention are organic or inorganic. These acids include, but are not limited to, the inorganic acids nitric, sulfuric, phosphoric and hydrochloric acids and the organic acids formic, acetic, propionic, n-butyric, isobutyric, benzoic, ascorbic, gluconic, malic, malonic, oxalic, succinic, tartaric, citric, gallic. The latter five organic acids are examples of chelating agents.

Concentrations of the acids can vary from about 1 to about 25 weight percent. It is preferable that the acid and base products are soluble with any additional agents in the aqueous solutions.

The caustic components suitable for use to adjust the pH of the cleaning solutions may be composed of any common base, such as, but not limited to, sodium, potassium, magnesium hydroxides, and the like. One problem associated with the use of these bases is the introduction of mobile ions into the final formulation. Such mobile ions could destroy computer chips currently being produced in the semiconductor industry. Other suitable bases include choline (a quaternary amine) and ammonium hydroxide.

To attain the desired pH, a basic compound may be added to the compositions of the invention. Suitable basic compounds include but are not limited to, alkylammonium hydroxides and alkanolamines. Alkylammonium hydroxides include, but are not limited to, tetramethyl ammonium hydroxide (TMAH), tetraethyl ammonium hydroxide and the like. Alkanolamines include, but are not limited to, methanolamine (MEA), ethanolamine, diethanolamine, isopropanolamine, diglycolamine and the like. Choline compounds may also be used and include, but are not limited to, choline hydroxide, bis-hydroxyethyl dimethyl ammonium hydroxide, and tris-hydroxyethyl methyl ammonium hydroxide. Ammonium hydroxide and isopropanolamine are particular examples of suitable basic compounds and may be added to the compositions while monitoring pH to ensure that the complete compositions have the desired pH. Table 1 shows the cleaning performance for compositions that do not comprise PGME from pH 2 to 8 for the chemicals. Table 2 shows the cleaning performance for chemicals that do comprise PGME at a fixed pH of 3.0.

The cleaning compositions contain water. In an exemplary embodiment, high purity deionized water (DIW) is used. In one embodiment, the water is present from 20% to 60% by weight in compositions comprising DMAC. In compositions comprising PGME or propylene glycol, water may be present from 90% to 98% by weight of the composition.

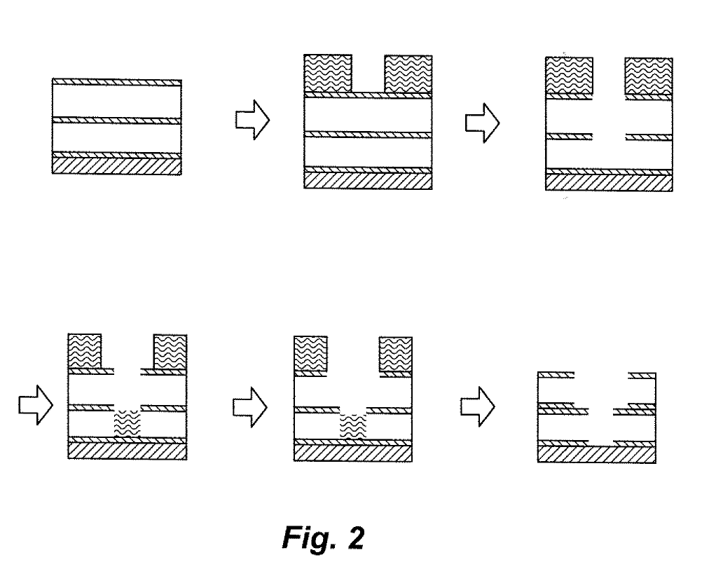

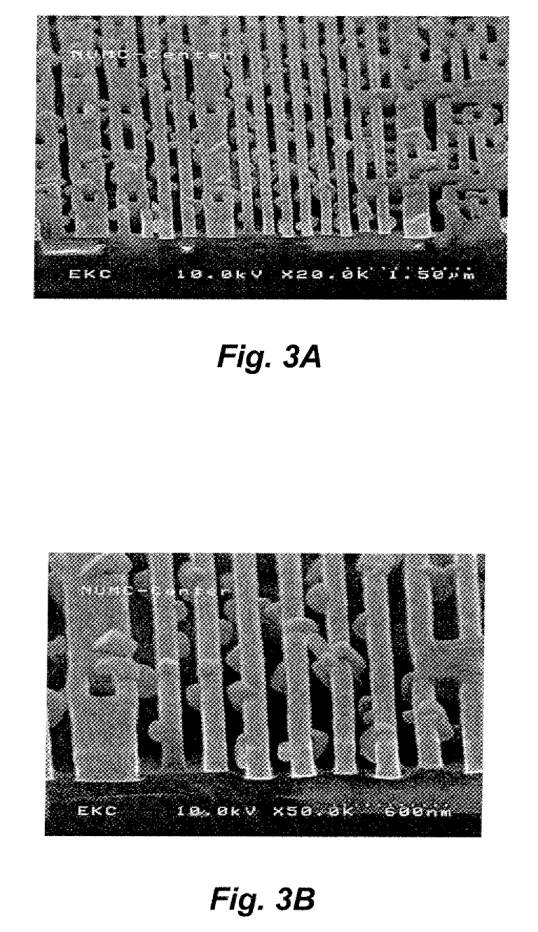

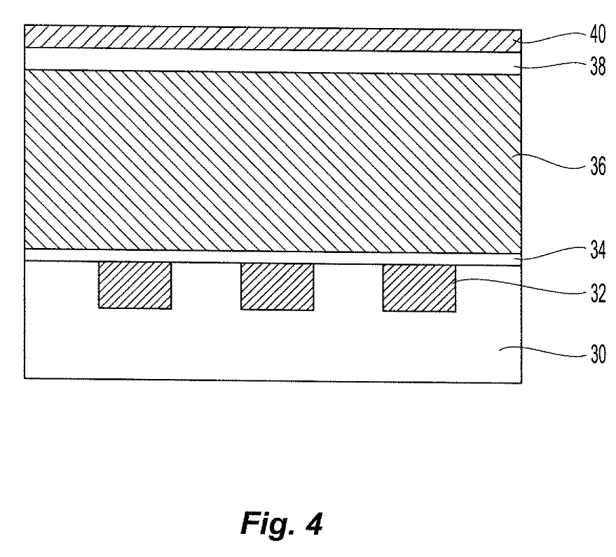

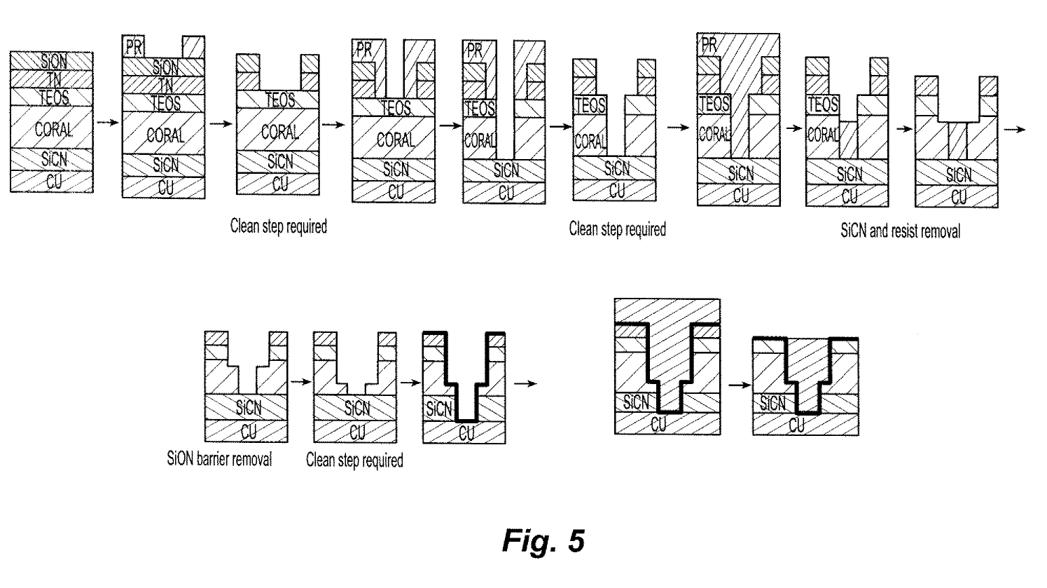

A description of the dual damascene process using dual hard masks is provided in U.S. Pat. No. 6,696,222, which is provided herein by reference in its entirety. More particularly, this process is best described in FIGS. 2a-2k of this patent and in the accompanying text (see col. 3, line 13—col. 4, line 38).

The compositions of the invention are useful for removing one or more of etching residue from metal hard mask, and metal oxide from a substrate having titanium, titanium nitride, tungsten, chromium, aluminum or mixtures thereof. The substrates most often will be the wiring layers of integrated circuits such as memory or logic. The compositions of this invention are most useful for substrates whose surface comprises a metal hard mask such as titanium nitride. Typical etching residue include TiF inorganic contaminants, polymer etching residues and a mixture of copper oxide and polymer.

In one embodiment of the invention, polymer removal after the etching step of a dual damascene opening process is described as an example, which is not intended to restrict the scope of the invention.

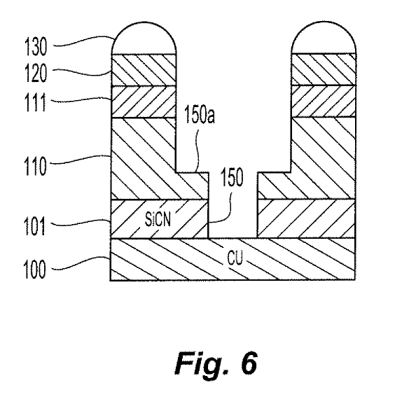

Referring to FIG. 6, an example of metal hard mask dual damascene opening processes is demonstrated. A dielectric layer such as coral (110) is formed on a substrate such as copper (100) first and silicon carbonitride second, wherein the material of the dielectric layer (110) may be coral or silicon oxide or a silicon-based low-k material. Another dielectric layer (111) may be formed, such as TEOS. A hard mask layer (120), such as a titanium nitride (TiN) layer is then formed on the dielectric layer 111. When the material of the hard mask layer (120) is a metallic material like titanium nitride (TiN), intermediate layers are usually formed under and above the hard mask layer (120).

Then, the hard mask layer (120) is defined to form a via hole pattern, and the exposed dielectric layer (111) is etched to formed a pre-via hole (150a). A patterned photoresist layer (130) defining a trench is formed on the hard mask layer (120), and then an anisotropic dry etching step is performed to etch the exposed dielectric (110) using the patterned photoresist layer (130) as a mask. With the etching step, the pre-via hole (150a) is made deeper to form a via hole (150), and a trench (160) is also formed, while the photoresist layer (130) and the upper intermediate layer (124) are etched away. The via hole (150) and trench (160) together constitute a dual damascene opening (170), wherein the sidewalls of the via hole (150) and trench (160) is formed with polymer (180) as an etching residue thereon.

### H. Operation

The method of cleaning a substrate using the cleaning compositions of the present invention involves contacting a metal hard mask substrate having residue thereon, for example, polymeric, organometallic or metal oxide residues, with a cleaning composition of the present invention for a time and at a temperature sufficient to remove the residues. Stirring, agitation, circulation, sonication or other techniques as are known in the art may optionally be used. In one embodiment, the he substrate is immersed in the cleaning composition. The time and temperature are determined based on the particular material being removed from a substrate. In one embodiment, the temperature is in the range of from about ambient or room temperature to 100° C. and the contact time is from about 30 seconds to 60 minutes. In another embodiment, the temperature and time of contact are 20 to 50° C. from 2 to 60 minutes, such as 5 minutes. In one embodiment, the substrate is rinsed after using the composition. Preferred rinse solutions include, but are not limited to, isopropanol and DI water or neat DI water.

In a particular embodiment, when the metal hard mask layer is titanium nitride, the etching residues are titanium fluoride (TiₓF_{y}) and silicon fluoride. In another particular embodiment, when the substrate is copper, the etching residue comprises copper oxide (CuₓO), polymers or mixtures thereof.

### III. Examples

Exemplary embodiments of the present invention will be illustrated by reference to the following examples, which are included to exemplify, but not limit the scope of the present invention.

TABLE 1
Cleaning performance from pH 1 to 8 for the cleaning
compositions 1 through 10 for examples 1-10.

| | Ammonium | | DMAC | Water | | Cleaning |
|---|---|---|---|---|---|---|
| Composition | Bifluoride | Acids (wt %) | (wt %) | (wt %) | pH | Results |
| 1 | 0.2 | Maleic acid 5 | 40 | 54.8 | 2.62 | 9 |
| 2 | 0.185 | Citric Acid 32.4 | 29.6 | 37.82 | 2.78 | 9 |
| 3 | 0.2 | Citric Acid 25 | 40 | 34.8 | 3.28 | 9 |
| 4 | 0.4 | Citric Acid 5.25 | 60 | 33.35 | 4.9 | 9 |
| 5 | 0.4 | Citric Acid 5.25 | 60 | 34.35 | 5.12 | 9 |
| 6 | 0.6 | Citric Acid 3.0 | 60 | 23.4 | 5.7 | 9 |
| 7 | 0.8 | MEA 0.5 | 65.4 | 33.3 | 8.0 | 9 |
| 8 | 0.12 | | 26 | 21.88 | 8.06 | 3 |
| (EKC-6910) | | | | | | |
| 9 | 0.2 | TMAH 0.25 | 39.55 | 39.55 | 8.11 | 3 |
| 10 | 0.4 | TMAH 3.0 | 36.6 | 36.6 | 13.8 | 3 |

The cleaning results are reported on a scale of 1 (poor) to 10 (excellent).

### Example 1

A composition 1 for the removal of metal hard mask residue was prepared comprising 0.2 weight percent ammonium bifluoride, 5% maleic acid, 40% DMAC, 54.8% DIW at a pH of 2.62.

### Example 2

A composition 2 for the removal of metal hard mask residue was prepared comprising 0.185 weight percent ammonium bifluoride, 32.4% citric acid, 40% DMAC, 54.8% DIW at a pH of 2.62.

### Example 3

A composition 3 for the removal of metal hard mask residue was prepared comprising 0.2 weight percent ammonium bifluoride, 25% citric acid, 40% DMAC, 34.8% DIW at a pH of 3.28.

### Example 4

A composition 4 for the removal of metal hard mask residue was prepared comprising 0.4 weight percent ammonium bifluoride, 5.25% citric acid, 60% DMAC, 1% DDBSA, 33.35% DIW at a pH of 4.9

### Example 5

A composition 5 for the removal of metal hard mask residue was prepared comprising 0.4 weight percent ammonium bifluoride, 5.25% citric acid, 60% DMAC, 1% DDBSA, 34.35% DIW at a pH of 5.12.

### Example 6

A composition 6 for the removal of metal hard mask residue was prepared comprising 0.6 weight percent ammonium bifluoride, 3% citric acid, 60% DMAC, 1% DDBSA, 23.4% DIW at a pH of 5.7.

### Example 7

A composition 7 for the removal of metal hard mask residue was prepared comprising 0.8 weight percent ammonium bifluoride, 0.5 MEA, 65.4% DMAC, 1% DDBSA, 33.3% DIW at a pH of 8.

### Example 8

A composition 8 for the removal of metal hard mask residue was prepared comprising 0.12 weight percent ammonium bifluoride, 48.5% DGBE, 26% DMAC, 2% DEEA, 1.5% Sulfamic acid, 21.88% DIW at a pH of 8.06.

### Example 9

A composition 9 for the removal of metal hard mask residue was prepared comprising 0.2 weight percent ammonium bifluoride, 0.25 MEA, 60% DMAC, 39.55% DIW at a pH of 8.11.

### Example 10

A composition 10 for the removal of metal hard mask residue was prepared comprising 0.4 weight percent ammonium bifluoride, 3.0% TMAH, 60% DMAC, 36.6% DIW at a pH of 13.8.

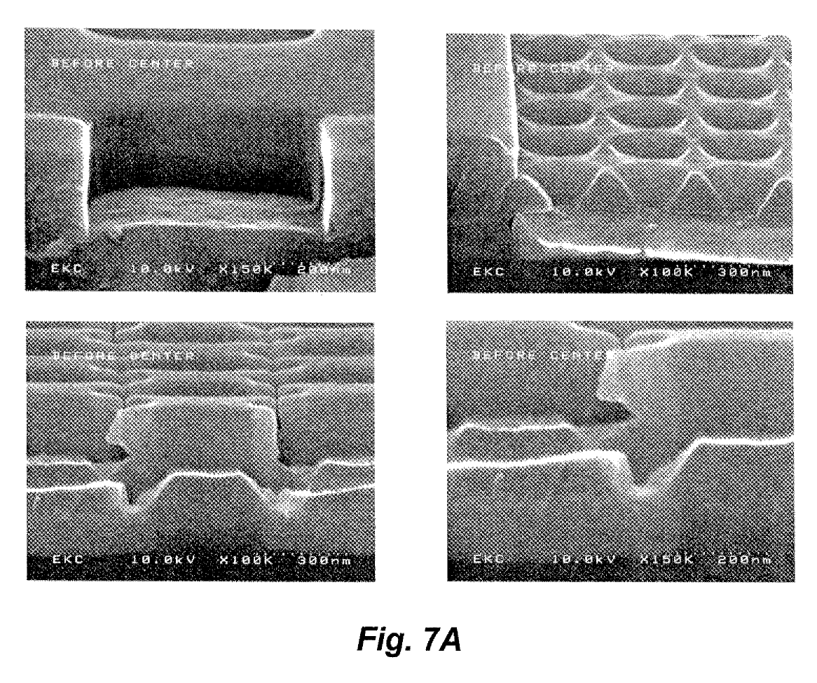

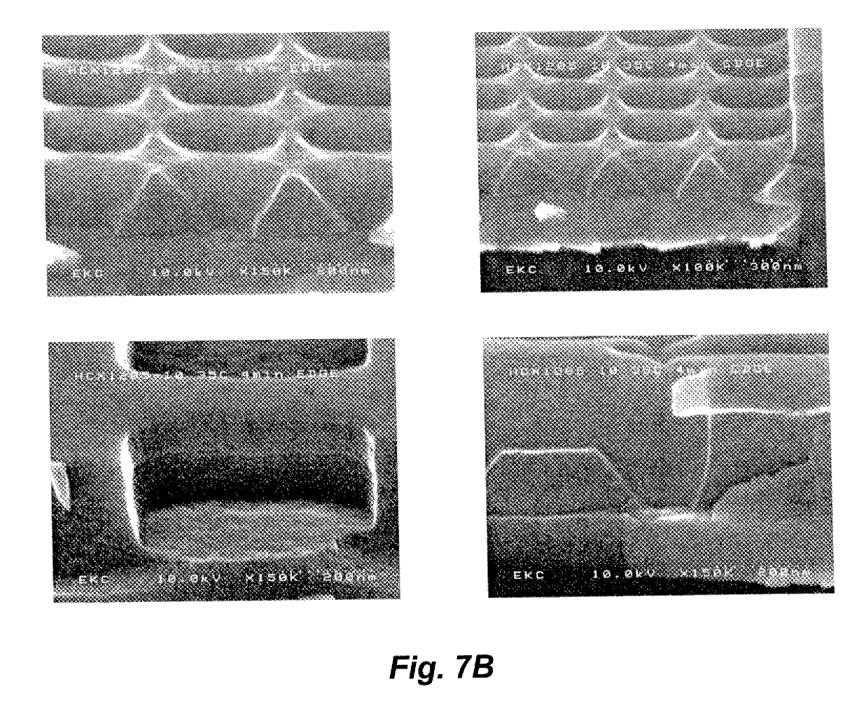

FIG. 7A demonstrates an examination under a Scanning Electron Microscope (SEM), Hitachi SEM 6400, which shows the central feature of a metal hard mask substrate before etching process. FIG. 7B demonstrates an examination under a Scanning Electron Microscope (SEM), Hitachi SEM 6400, which shows the edge feature of a metal hard mask substrate before etching process.

FIG. 7B demonstrates the Scanning Electron Microscope (SEM), Hitachi SEM 6400, which shows the central feature of a metal hard mask substrate or the via hole patterned feature after etching processes according to general procedures using a composition of example 3. The patterned substrate was immersed in separate beakers containing Composition 3 for 5 minutes at 50° C. The substrates were then rinsed in deionized water and dried by blowing nitrogen across the substrate surfaces.

TABLE 2
Cleaning compositions for removal of metal hard
mask etching residues at a pH of about 3.

| | Ammonium | | | | | % By | Other |
|---|---|---|---|---|---|---|---|
| | Bifluoride | | | Organic | | Weight of | Organic |
| Composition | wt % | Compound | Weight % | Acid | Weight % | Water | Acid |
| 11 | 0.1 | PGME | 2.6 | Glycolic | 2.0 | 95.3 | |
| | | | | acid | | | |
| 12 | 0.1 | PGME | 2.6 | Glycolic | 2.0 | 95.25 | 0.05 |
| | | | | acid | | | IDA |
| 13 | 0.1 | PGME | 2.6 | Citric | 1.5 | 95.8 | |
| | | | | Acid | | | |
| 14 | 0.1 | PGME | 2.6 | Citric | 1.5 | 95.75 | 0.05 |
| | | | | Acid | | | IDA |
| 15 | 0.1 | PG | 2.6 | Citric | 1.5 | 95.8 | |
| | | | | Acid | | | |
| 16 | 0.075 | PGME | 2.6 | Citric | 2.0 | 95.33 | |
| | | | | Acid | | | |
| 17 | 0.1 | | | Glycolic | 2.0 | 97.9 | |
| | | | | acid | | | |
| 18 | 0.1 | PGME | 2.6 | | | 97.3 | |
| 19 | 0.13 | PGME | 6.495 | Citric | 2.125 | 90.95-90.25 | 0.3-1% |
| | | | | Acid | | | DDBSA |
| 20 | 0.13 | PGME | 6.495 | Citric | 2.125 | 91.25 | |
| | | | | Acid | | | |
| 21 | 0.13 | PGME | 6.495 | | | 92.38 | 1% |
| | | | | | | | DDBSA |
| 22 | 0.4 | DMAC | 60 | Citric | 5 | 34.6 | |
| | | | | Acid | | | |
| 23 | 0.2 | DMAC | 60 | Citric | 3 | 33.8 | 3% |
| | | | | Acid | | | DDBSA |
| 24 | 0.4 | DMAC | 60 | Citric | 3 | 33.6 | 1% |
| | | | | Acid | | | DDBSA |
| 25 | 0.07 | PG | 3.93 | Citric | 1 | 95 | |
| | | | | Acid | | | |
| 26 | 0.0525 | PG | 3.93 | Citric | 1 | 95.0175 | |
| | | | | Acid | | | |
| 27 | 0.0350 | PG | 3.93 | Citric | 1 | 95.035 | |
| | | | | Acid | | | |
| 28 | 0.0175 | PG | 3.93 | Citric | 1 | 95.0525 | |
| | | | | Acid | | | |

### Example 11

A composition 11 for the removal of metal hard mask residue was prepared comprising 0.1 weight percent ammonium bifluoride, 2.6% PGME, 2.0% Glycolic acid, 95.3% water at a pH of about 3.0.

### Example 12

A composition 12 for the removal of metal hard mask residue was prepared comprising 0.1 weight percent ammonium bifluoride, 2.6% PGME, 2.0% Glycolic acid, 95.25% water, 0.5% IDA at a pH of about 3.0.

### Example 13

A composition 13 for the removal of metal hard mask residue was prepared comprising 0.1 weight percent ammonium bifluoride, 2.6% PGME, 1.5% Citric Acid, 95.8% water, at a pH of about 3.0.

### Example 14

A composition 14 for the removal of metal hard mask residue was prepared comprising 0.1 weight percent ammonium bifluoride, 2.6% PGME, 1.5 Citric Acid, 95.75% water, 0.05% IDA at a pH of about 3.0.

### Example 15

A composition 15 for the removal of metal hard mask residue was prepared comprising 0.1 weight percent ammonium bifluoride, 2.6% PGME, 1.5 Citric Acid, 95.8% water, at a pH of about 3.0.

### Example 16

A composition 16 for the removal of metal hard mask residue was prepared comprising 0.075 weight percent ammonium bifluoride, 2.6% PGME, 2.0% Glycolic acid, 95.33% water at a pH of about 3.0.

### Example 17

A composition 17 for the removal of metal hard mask residue was prepared comprising 0.075 weight percent ammonium bifluoride, 2.0% Glycolic acid, 97.9% water at a pH of about 3.0.

### Example 18

A composition 18 for the removal of metal hard mask residue was prepared comprising 0.075 weight percent ammonium bifluoride, 2.6% PGME, 97.3% water at a pH of about 3.0.

### Example 19

Two compositions 19 for the removal of metal hard mask residue were prepared comprising 0.13% weight percent ammonium bifluoride, 6.495% PGME, 2.125% Citric acid, 0.3-1% DDBSA, 90.95-90.25% water at a pH of about 3.0.

### Example 20

A composition 20 for the removal of metal hard mask residue was prepared comprising 0.13% weight percent ammonium bifluoride, 6.495% PGME, 2.125% citric acid, 91.25% water at a pH of about 3.0.

### Example 21

A composition 21 for the removal of metal hard mask residue was prepared comprising 0.13% weight percent ammonium bifluoride, 6.495% PGME, 1% DDBSA, 92.38% water at a pH of about 3.0.

### Example 19

Two compositions 19 for the removal of metal hard mask residue were prepared comprising 0.13% weight percent ammonium bifluoride, 6.495% PGME, 2.125% Citric acid, 0.3-1% DDBSA, 90.95-90.25% water at a pH of about 3.0.

### Example 22

A composition 22 for the removal of metal hard mask residue was prepared comprising 0.4% weight percent ammonium bifluoride, 60% DMAC, 3% Citric acid, 3% DDBSA, 33.8% water at a pH of about 3.0.

### Example 23

A composition 23 for the removal of metal hard mask residue was prepared comprising 0.4% weight percent ammonium bifluoride, 60% DMAC, 3% Citric acid, 3% DDBSA, 33.8% water at a pH of about 3.0.

### Example 22

A composition 22 for the removal of metal hard mask residue was prepared comprising 0.4% weight percent ammonium bifluoride, 60% DMAC, 5% Citric acid, 34.6% water at a pH of about 3.0.

### Example 23

A composition 23 for the removal of metal hard mask residue was prepared comprising 0.2% weight percent ammonium bifluoride, 60% DMAC, 3% Citric acid, 3% DDBSA, 33.8% water at a pH of about 3.0.

### Example 24

A composition 24 for the removal of metal hard mask residue was prepared comprising 0.4% weight percent ammonium bifluoride, 60% DMAC, 3% Citric acid, 1% DDBSA, 33.6% water at a pH of about 3.0.

### Examples 25-28

A composition 25 for the removal of metal hard mask residue was prepared comprising 0.07% weight percent ammonium bifluoride, 3.93% propylene glycol, 1% Citric acid, 95% water at a pH of about 3.0. Three more compositions were prepared with 75%, 50%, and 25% of the amount of ammonium bifluoride as composition 25.

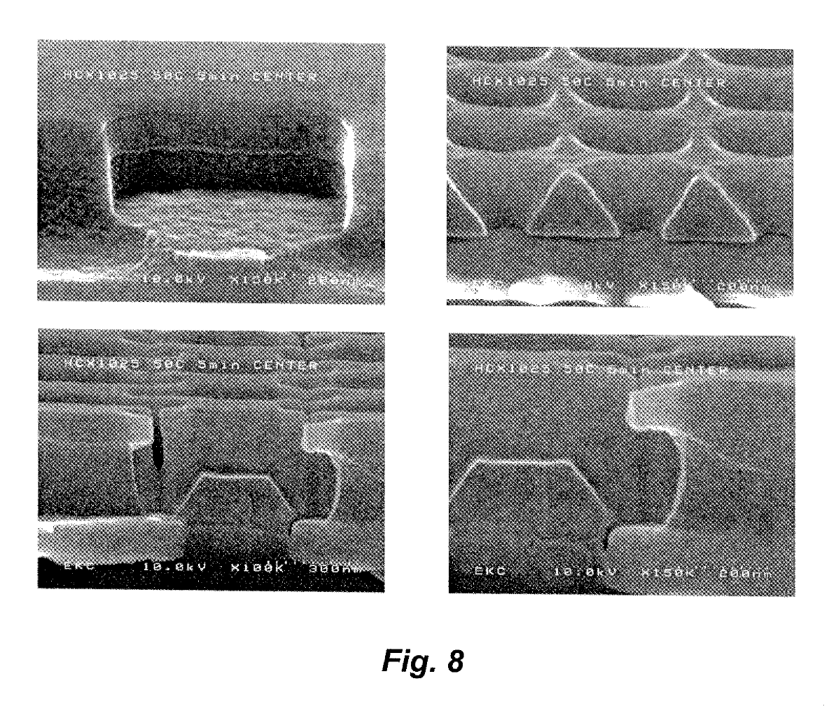

For example, FIG. 8 demonstrates an examination under a Scanning Electron Microscope (SEM), Hitachi SEM 6400, which shows the via hole patterned feature after etching processes according to general procedures described above using a composition of example 20. The patterned substrate was then immersed in beakers containing composition of example 20 for 8 minutes at 35° C. The substrates were then rinsed in de-ionized water and dried by blowing nitrogen across the substrate surfaces.

It was surprisingly and unexpectedly found that examples without TMAH being present gave good cleaning results. Further, it was unexpectedly found that a pH of greater than 8 did not result in good cleaning of the metal hard mask residues but that good cleaning results were obtained at a pH in the range of about 1 to 8. It was also unexpectedly found that compositions with propylene glycol monoethyl ether present but without N,N dimethylacetamide present produced good results.

Although the foregoing invention has been described in some detail for purposes of clarity of understanding, it will be apparent that certain changes and modifications may be practiced within the scope of the appended claims. For example, while the specification describes introducing the ammonium bifluoride for metal hard mask cleaning and stripping, there is no reason why in principle the ammonium bifluoride compound of the present invention cannot be introduced in other application involving copper, such as a post-CMP application. Therefore, the present embodiments are to be considered as illustrative and not restrictive, and the invention is not to be limited to the details given herein, but may be modified within the scope of the appended claims. All patents and published applications referenced herein are incorporated in their entireties.

Having described the invention in detail, those skilled in the art will appreciate that, given the present disclosure modifications may be made to the invention without departing from the spirit of the inventive concept described herein. Therefore, it is not intended that the scope of the invention be limited to the specific embodiments illustrated and described.

What is claimed is:

1. A composition for removing one or more of resist, etching residue, planarization residue, metal fluoride and metal oxide from a substrate, the composition comprising:
a) a metal ion-free fluoride compound selected from the group consisting of ammonium fluoride, ammonium bifluoride, HF and mixtures thereof;
b) one or more acids; and
c) water,
wherein the pH of the composition is from about 1 to 8, and
wherein the one or more of resist; etching residue, planarization residue, metal fluoride and metal oxide is generated during one or more patterning processes during which a metal hard mask is used.

2. The composition of claim 1, further comprising one or more polar organic solvents selected from the group consisting of amides, alcohol amines, polyols and mixtures thereof.

3. The composition of claim 2, wherein the one or more polar organic solvents comprises N,N dimethylacetamide.

4. The composition of claim 1, wherein the metal ion-free fluoride compound is ammonium bifluoride.

5. The composition of claim 4, wherein the ammonium bifluoride is present from about 0.01 to about 1.0 percent by weight.

6. The composition of claim 1, wherein the one or more acids comprises a carboxylic acid.

7. The composition of claim 6, wherein the carboxylic acid is selected from the group consisting of iminodiacetic acid, acetic acid, maleic acid, glyoxylic acid, citric acid, oxalic acid, gallic acid, formic acid, glycolic acid and mixtures thereof.

8. The composition of claim 7, wherein the carboxylic acid is present in the range of from about 0.5% to about 35% by weight.

9. A composition for removing one or more of resist, etching residue, planarization residue, metal fluoride and metal oxide, the composition comprising:
a) a metal ion-free fluoride compound;
b) one or more acids;
c) a compound selected from the group consisting of ethers, glycol ethers, amides, alcohol amines, polyols and mixtures thereof; and
d) water,
wherein the pH of the composition is from about 1 to about 8, and
wherein the one or more of resist, etching residue, planarization residue, metal fluoride and metal oxide is generated during one or more patterning processes during which a metal hard mask is used.

10. The composition of claim 9 wherein component c) comprises propylene glycol and/or one or more of propylene glycol monoethyl ether, diethylene glycol monomethyl ether, diethylene glycol monobutyl ether, or mixtures thereof, and wherein component c) is present in a range from about 2% to about 7% by weight.

11. The composition of claim 9, wherein component c) comprises N,N dimethylacetamide present in a range up to about 60% by weight.

12. The composition of claim 9, wherein the metal ion-free fluoride compound is ammonium bifluoride present in a range from about 0.05 to about 1 percent by weight.

13. The composition of claims 1 or 9 further comprising a chelating agent.

14. The composition of claim 1 further comprising monoethanolamine present in a range from about 0.05 to 1% by weight.

15. The composition of claim 9, comprising ammonium bifluoride, citric acid, propylene glycol and water.

16. A method for removing one or more of resist, etching residue, planarization residue, metal fluoride and metal oxide from a semiconductor substrate, the method comprising contacting the substrate with the composition of claim 1 or 9 for a period of time and at a temperature sufficient to remove one or more of the resist, etching residue, planarization residue, metal fluoride and metal oxide,
wherein one or more of the resist, etching residue, planarization residue, metal fluoride and metal oxide is generated during one or more patterning processes during which a metal hard mask is used, and
wherein the composition has a pH between 1 and 8.

17. The method of claim 16, wherein the metal hard mask comprises titanium nitride, tantalum nitride, tungsten, chromium, aluminum oxide, aluminum nitride, or mixtures thereof.

18. The method of claim 16, wherein the hard mask etching residue comprises titanium fluoride (TiₓF_{y}), silicon fluoride inorganic residues, copper oxide (CuₓO), polymers, or mixtures thereof.
